(19) United States
(12) Patent Application Publication
(10) Pub. No.: US 2014/0186527 A1
(43) Pub. Date: Jul. 3, 2014

(54) Device and method for processing strip-type substrates

(71) Applicant: AIXTRON SE, Herzogenrath (DE)

(72) Inventors: Kenneth B.K. Teo, Cambridge (GB); Nalin Rupesinghe, Cambridge (GB)

(73) Assignee: AIXTRON SE, Herzogenrath (DE)

(21) Appl. No.: 14/091,222

(22) Filed: Nov. 26, 2013

(30) Foreign Application Priority Data
Nov. 27, 2012 (DE) 102012111484.6

(51) Int. Cl. C23C 16/26; C23C 16/458

(52) U.S. Cl. CPC C23C 16/26; C23C 16/458
USPC 427/177; 118/718

(57) ABSTRACT

The invention relates first to a device for processing a strip-type substrate (1), in particular by coating, in a processing chamber (2), using a processing roller (3) mounted to rotate about an axis of rotation (18) in the processing chamber (2), such that the substrate (1), which is unwound from a first coil (6) with which it is in contact in a helical pattern is processed continuously, wherein the processed, in particular coated, substrate (1) is wound onto a second coil (7), wherein a gas inlet/outlet device (8, 9, 10) is provided for generating a gas stream (11, 12) directed essentially in parallel to the axis of rotation (18). In addition, the invention relates to a method for coating a strip-type substrate (1) in a device.

The invention relates to a device for processing, in particular coating a strip-type substrate in a processing chamber, having a processing roller mounted to rotate about an axis of rotation in the processing chamber, such that the lateral surface of this processing roller is in helical contact with a substrate unwound from a first coil, is processed continuously, in particular being coated continuously, wherein the processed, in particular coated, substrate is wound onto a second coil.

Such a device is described in JP 2005-133 165 A. The processing roller is a cylindrical body arranged in a cylindrical cavity in a housing.

WO 2011/081 440 A2 describes a device with which the processing roller is immersed in a bath in some regions.

WO 2012/134 205 A1 describes a device in which a strip-type substrate passes continuously through a process chamber. No processing roller is provided here.

US 2012/0 234 240 A1 and US 2011/0 195 207 A1 describe graphene coating equipment with which a strip-type substrate is passed through a processing chamber where it is coated. This is done without a processing roller.

WO 2012/0 287 776 A1 describes a device with which a strip-type substrate that is to be coated is deflected repeated and then is directed through an arc-shaped processing chamber where it rests on a plurality of rollers. The outer wall of the processing chamber radially forms a plurality of nozzle heads through which process gases are introduced into the processing chamber. The process gas is introduced across the plane of extent of the strip-type substrate.

EP 2 360 293 A1 describes a similar device. Here again, the substrate is coated in a processing chamber with a ring slot shape. Here again, however, it does not rest on a plurality of rollers but instead comes in contact with one roller. Here again, the gas is supplied radially to the axis of the process chamber.

U.S. Pat. No. 6,630,058 B2 describes a coating device for a strip-type substrate in which a target is arranged next to a processing roller in the radial direction. Conductive materials are sputtered from the target and reach the substrate in the radial direction.

GB 2 458 776 A describes a device for coating a continuous substrate which is passed through an elongated processing chamber. The substrate enters and exits from the processing chamber through one end. At the other end of the processing chamber, there is a ring-shaped deflecting device but no processing roller is provided here.

US 2011/0 315 657 A1 describes a coating device for coating a continuous substrate which is passed through a processing chamber without being deflected.

U.S. Pat. No. 5,932,302 describes a device for coating a continuous substrate with a carbon-based coating where the substrate is guided along the surface of a processing roller. The starting materials are transported radially onto the processing roller.

U.S. Pat. No. 5,711,814 A describes a method for depositing a thin film on a substrate, where a rotating electrode is provided and the substrate is transport passed it. A reactive gas is introduced into the gap between the substrate surface and the electrode surface. This is where a plasma is supposed to develop

EP 0 782 176 B1 describes a method for depositing a layer on a continuously transported sheet-type substrate. For transporting the substrate, a roller having a surface that is curved in the axial direction is provided, among other things.

EP 1 999 296 B1 describes a device and a method for coating a strip-type substrate. This substrate is guided over a processing roller. A process gas introducing element which creates a process gas in the gap between the process gas introducing element and the substrate sits next to the processing roller. A gas stream that is generated can flow in this gap either in the circumferential direction or in the axial direction with respect to the processing roller.

EP 2 1113 535 A1 [sic] describes a conveyor device consisting of a plurality of rollers for conveying a strip-type substrate through a processing chamber in which a processing roller on which the substrate rests is arranged. A process gas is introduced by means of a gas inlet element into a gap between the substrate and the gas inlet element.

WO 2010/144 302 A1 describes a CVD coating device for applying a layer to a strip-type substrate, wherein the substrate is passed through a plurality of successive processing chambers.

The object of the invention is to provide a device and a method with which strip-type substrates can be coated with a layer of graphene or a layer of nanotubes in a continuous pass and which will have an advantage in terms of the process engineering in comparison with the devices and methods known from the prior art.

This object is achieved by an invention as defined in the claims.

First and foremost, the device has a first coil on which a strip-type substrate is wound. The strip-type substrate may have a width of a few millimeters of up to several meters. The processing chamber may be a vacuum chamber. A processing roller which has a sufficient axial length to accommodate multiple windings of the strip-type substrate on its lateral surface is provided in the processing chamber. According to the invention, a gas stream directed essentially parallel to the axis of rotation of the processing roller is generated by a gas inlet/outlet device. A gas flow field completely surrounding the processing roller is formed and the substrate is conveyed through it with the rotation of the processing roller. This gas stream passes through this ring-shaped gas flow field essentially at a right angle to the surface normal of the substrate. The substrate unwound from the first coil is coated continuously while in contact with the roller in a helical pattern. To do so, the processing roller is rotated continuously about its axis of rotation. The coated substrate is wound onto a second coil. According to the invention, the device in particular the processing chamber has a gas inlet device and/or a gas outlet device. This gas inlet/outlet device is designed so that it creates a gas stream directed essentially parallel to the axis of rotation. The gas stream has a flow directed parallel to the lateral surface of the processing roller. To create the at least one gas flow, the gas inlet/outlet device has gas inlet openings and/or gas outlet openings. The gas inlet openings are designed so that the gas stream leaves the gas inlet element in the axial direction with respect to the axis of rotation. The openings in the gas outlet element are also directed in the direction of flow. The openings in the gas inlet element and/or in the gas outlet element are arranged so that an axial flow develops along the entire circumferential surface of the processing roller. Two gas flow fields can develop. A purifying gas or purging gas is introduced by the first gas inlet element into the process chamber. The gas inlet element surrounding the processing roller in this regard, in particular in a ring shape may be arranged so that it is offset with respect to the center of the processing roller on the substrate inlet side. A purifying gas or purging gas flows from this gas inlet element to the center of the processing roller in the axial direction, where a gas outlet element surrounds the ring-shaped processing roller through which the purifying-purging gas leaves the process chamber. This gas outlet element is also capable of diverting a process gas out of the process chamber. A second gas inlet element which also surrounds the processing roller in a ring shape serves to introduce the process gas into the process chamber. The second gas inlet element is arranged with an offset from the axial center of the processing roller on the substrate outlet end. A heating device is also provided to heat the surface temperature of the processing roller and/or the gas temperature within the process chamber to a process temperature. The heating may be arranged outside of the processing roller. However, it is also possible to arrange the heating inside the processing roller. With this heating device, a temperature profile whose maximum temperature occurs in the axial center of the roller and/or in the area of the gas outlet element is created. The minimum temperature of the temperature profile occurs in the area of the two ends of the processing roller. When using a substrate made of copper, the maximum temperature may be 1085° C. or less. For a substrate made of aluminum, the maximum temperature may be 660° C. or less. The temperature in the end areas of the processing roller is approximately at room temperature or slightly higher. In a preferred embodiment of the processing roller, it is provided that in the area of its axial center it has a maximum diameter which is greater than the diameter in the area of its two ends. The roller may be the mirror symmetry with respect to an imaginary plane extending through its center, perpendicular to the axis of rotation. The lateral surface of the rotational body formed by the processing roller may run along a surface of a rotational paraboloid. In very general terms, the roller may have the shape of a Weber boat. The substrate is wound onto the processing roller at room temperature. In the wake of the continuous pass through the processing chamber, the substrate is heated up continuously to a temperature close to the melting point of the substrate. The increase in the diameter of the processing roller in the area of maximum surface temperature compensates for the longitudinal extent of the temperature of the substrate. The processing roller conveying the substrate in the axial direction may be made of stainless steel or of a ceramic material. The processing roller may be made of a uniform material or of various materials. The processing roller may also be made of a uniform material or of a variety of materials. It is also conceivable for the processing roller to be manufactured from a plurality of individual roller bodies that adjoin together fixedly or loosely. In the method according to the invention, carbon-based gases, which are introduced through a gas inlet element into the process chamber with the help of an inert carrier gas, are used as the process gases. The process gases flow through the process chamber in the direction opposite the direction of conveyance of the substrate. Preferably H₂, NH₃, Ar, N₂, CH₄, C₂H₄, C₂H₂ or C₆H₆ are used as process gases, but other gases or liquids may also be used. H₂, Ar, NH₃ are used as the purifying gas or purging gas. Here again other gases or even liquids may also be used. The purifying gases flow through the process chamber preferably in the direction of conveyance of the substrate, where the purification zone is situated upstream from the deposition zone in the direction of conveyance. With the method according to the invention, a carbonaceous layer is deposited on a substrate which may comprise at least one metal. The layer consists of graphene and/or nanotubes.

Exemplary embodiments of the present invention are explained in greater detail below with reference to the accompanying drawings, in which

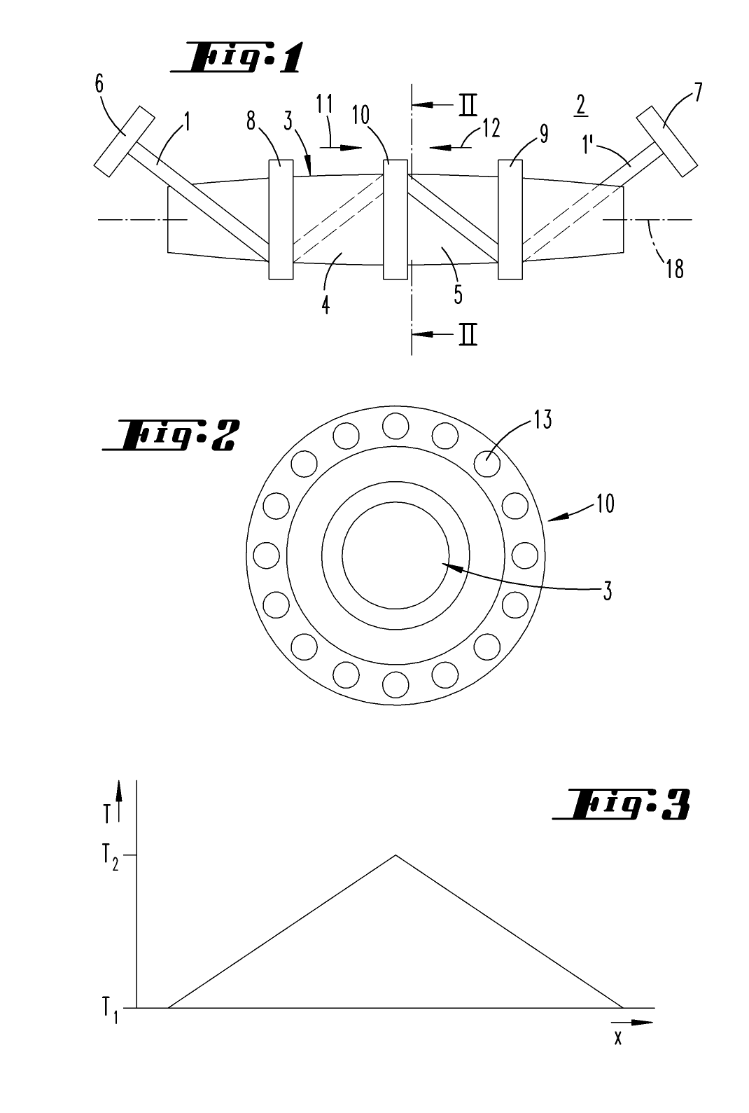

FIG. 1 shows the conveyor and coating device for a strip-type substrate 1;

FIG. 2 shows a section along line II-II in FIG. 1;

FIG. 3 shows the temperature profile on the surface of the processing roller 3 according to FIG. 1;

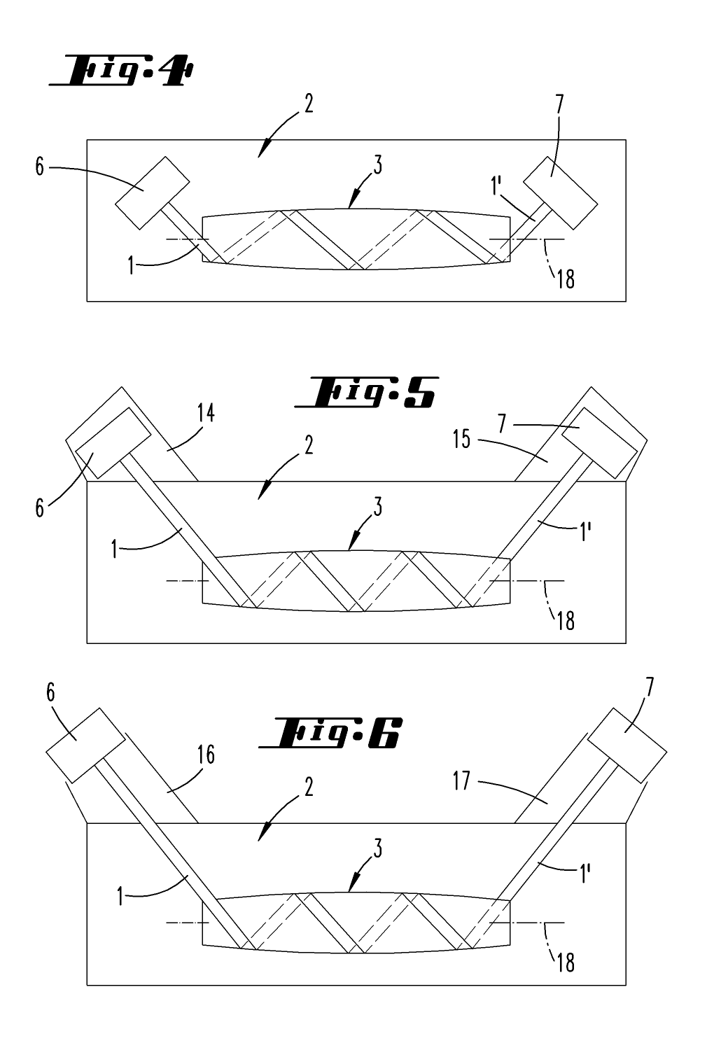

FIG. 4 shows a diagram according to FIG. 1, wherein the two coils 6, 7 for accommodating the coated and/or uncoated substrate 1 are situated within the process chamber 2;

FIG. 5 shows a diagram according to FIG. 1, wherein the coils 6, 7 are arranged inside the loading chamber 14, 15 and

FIG. 6 shows a diagram according to FIG. 1, wherein the substrate carriers formed by the coils 6, 7 are arranged outside of the process chamber 2 and are introduced into and/or removed from the process chamber 2 through gas-tight inlet zone 16, 17.

A method for depositing graphene layers or carbon nanotubes on substrates requires a process chamber in which great temperature differences are achievable. With the device and/or the method according to the invention, the continuous coating of a substrate which is not monocrystalline but which can be heated to a temperature close to its melting point for this purpose is possible. Substrates that may be considered include for example copper or aluminum. These are thin copper or aluminum foils which are wound onto a coil 6 in the form of a coil. According to the invention this strip-type substrate is applied to a processing roller on which it is processed with contact in the form of a helix. The processing roller 3 has a shape, such that its circumferential length and/or its diameter in the axial direction are varied in such a way that the greatest diameter occurs in the area of the highest temperature, and the smallest diameter is in the area of the lowest temperature. A purifying gas stream 11 and a process gas stream 12 are created with the gas inlet elements 8, 9, flowing parallel to the surface to a gas outlet element 10. The gas flows essentially in the direction of the axis of rotation 18 about which the processing roller 3 rotates.

FIG. 1 shows in general the design of a device according to the invention. The substrate 1 which is to be coated in the processing chamber 2 and which may have a width of a few millimeters up to several meters is provided on a coil 6. The substrate 1 passes obliquely to the axle 18 onto the processing roller 3 onto which it is wound and to whose lateral surface it is applied in a helical pattern. The substrate 1′, which is coated within the processing chamber 2, is wound onto a second coil 7.

Ring-shaped gas inlet elements 8, 9 and a ring-shaped gas outlet element 10 are provided.

Gas inlet element 8, which is arranged in a ring around the processing rotor 3, is situated at the inlet end of the substrate. An axial gas flow 11 emerges from the gas outlet opening assigned to the ring side wall. This is a purifying gas which may be H₂, Ar or NH₃. This purifying gas flows through the purification zone 4 and is removed by suction through a gas outlet element 10 situated approximately at the axial center of the processing roller. To do so, the gas outlet element 10 surrounding the processing roller 3 in the form of a ring has the openings 13 arranged in a ring pattern on the side wall shown in FIG. 2.

A second gas inlet element 9 which also surrounds the processing roller 3 in the form of a ring is provided at a distance from the gas outlet element 10 in the direction of flow. A process gas enters the deposition zone 5, flowing through wide side openings in the gas inlet element 9 in the direction of arrow 12 to the gas outlet element 10, where it is removed by suction. Gases that may be used as the process gas include H₂, NH₃, Ar, N₂, CH₄, C₂H₄, C₂H₂ or C₆H₆.

The gas inlet elements 8, 9 have gas outlet openings the arrangement of which corresponds to that of the openings 13, which are shown in FIG. 2 with respect to the gas outlet element 10.

As shown in FIG. 1, the process chamber 2 has zones 4, 5 situated in succession with respect to the direction of conveyance of the substrate 1. In the purification zone 4, the substrate 1 is purified at temperatures that increase in the direction of conveyance. The substrate is coated with a carbon-based structure namely graphene or nanotubes in the deposition zone 5, which is arranged downstream from the purification zone 4 in the direction of conveyance. The coating may be a pyrolytic surface process, but it may also involve a follow-up reaction of a gas-phase decomposition of the carbon-based deposition gas constituents. The number of windings with which the substrate is in contact with the processing roller 3 may essentially be selected freely. The windings may be so close together that the edges of the substrate 1 almost come in contact. However, the windings may also run at a distance from one another as illustrated in the drawings. The course of the windings is determined to a significant extent by the angle at which the substrate 1 is applied to the lateral surface of the processing roller 3.

FIG. 3 shows as an example a temperature profile along the axial direction 18 of the processing roller 3. The temperature T₁ which is room temperature or slightly above room temperature prevails in the area of the inlet zone (at the far left), i.e., in the area of the gas inlet element 8. The surface temperature of the processing roller 3 and/or a gas phase above the processing roller 3 increases continuously in the direction of conveyance, reaching its maximum value T₂ at the center of the roller, i.e., where the gas outlet element 10 is located. The temperature T₂ is slightly lower than the melting point of the substrate. The surface temperature of the processing roller 3 and/or the gas phase temperature above the roller 3 decreases continuously above the roller 3 in the direction of conveyance until reaching a value T₁ corresponding to room temperature and/or a value above that on reaching the inlet element 9 (far right).

FIGS. 4 to 6 show different variants of the invention, wherein the processing chamber 2 is shown explicitly. This is a vacuum chamber, which can be purged with an inert gas and is connected to a vacuum pump, so that process pressures in the range below atmospheric pressure can be set. These exemplary embodiments also have three different gas nozzles in the form of two gas inlet elements 8, 9 and one gas outlet element 10, as shown in FIGS. 1 and 2. For the sake of an overview, these gas inlet-outlet elements are not shown here. All the inlet-outlet nozzles 8, 9, 10 however are designed in a ring shape and surround the lateral surface of the processing roller 3 in the circumferential direction at a uniform distance. Therefore, they are arranged coaxially with the processing roller 3. Here again, the gas feed is parallel to the axis 18 of the processing roller 3 so that gas flows 11, 12 develop, flowing in the axial direction 18. As in the exemplary embodiment shown in FIG. 1, they may also flow in the opposite direction. The gas outlet and/or gas inlet is/are provided by openings 13 extending over the entire circumferential distance of a side wall of a gas inlet and/or out element 8, 9, 10.

The purifying gas and/or the unspent process gas are removed by suction through the central gas outlet element 10 which is located in the area of the largest roller diameter and approximately at the axial center.

FIG. 4 shows an arrangement in which the two coils 6, 7 are arranged inside the process chamber.

FIG. 5 shows an arrangement in which the two coils 6, 7 are arranged outside of the process chamber 2. Loading chambers 14, 15, which accommodate the coils 6, 7, are flange-connected here to the process chamber 2. The loading chambers 14, 15 can be closed with respect to the process chamber 2 by ports (not shown here), so that the process chamber 2 can be kept under vacuum conditions during a coil change.

With the exemplary embodiment illustrated in FIG. 6, the coils 6, 7 are arranged outside of the process chamber 2. Inlet zones 16, 17 through which the substrate 1 entering the process chamber 2 and/or the substrate 1′ exiting the process chamber 2 can pass are provided.

To compensate for the thermal expansion of the substrate 1 on the lateral surface of the processing roller 3, which occurs due to the temperature gradient, there is a correlation between the surface temperature and the diameter. The local diameter depends on the local surface temperature, such that regions of a higher temperature have a larger diameter than the region of a lower temperature. In this way, stresses within the substrate in coating are prevented. The processing roller 3 has a longitudinal cross section, such that the strip-type substrate 1 can be conveyed over the lateral surface of the roller 3 essentially free of stresses at a given temperature profile. Therefore there is no stretching within the substrate 1′ in particular in the zone with a declining temperature in the direction of conveyance. The change in length of the substrate which is influenced by the temperature gradient is essentially compensated with the varying diameter in the axial direction.

The preceding discussion serves to explain the present inventions, which are covered on the whole by the present patent application, and to further refine the prior art thereof through the following combinations of features, independently in each case, namely:

A device which is characterized in that for processing in particular coating a strip-type substrate (1) in a processing chamber (2), using a processing roller (3) mounted to rotate about an axis of rotation (18) in the processing chamber (2), such that the substrate (1), which is unwound from a first coil (6) with which it is in contact in a helical pattern, is processed continuously, wherein the processed, in particular coated, substrate (1) is wound onto a second coil (7), wherein a gas inlet/ outlet device (8, 9, 10) is provided for generating a gas stream (11, 12) directed essentially in parallel to the axis of rotation (18), forming a gas flow field extending around the entire circumference of the processing roller.

A device which is characterized in that the gas inlet/outlet device (8, 9, 10) has a gas inlet element (8, 9).

A device which is characterized in that the gas inlet/outlet device (8, 9, 10) has a gas inlet element (10).

A device which is characterized in that the gas inlet element (8, 9) is designed in a ring shape.

A device which is characterized in that the gas outlet element (10) is designed in a ring shape.

A device which is characterized by a purification zone (4) and a deposition zone (5) arranged at an offset therefrom in the direction of the axis of rotation (18).

A device which is characterized in that the ring-shaped gas inlet element (8, 9) has openings (13) opening in the direction of the axis of rotation (18).

A device which is characterized in that the ring-shaped gas outlet element (10) has openings (13) opening in the direction of the axis of rotation (18).

A device which is characterized in that a gas outlet element (10) surrounding the processing roller (3) in a ring shape approximately at its axial center for accommodating a purifying gas and/or a process which is introduced in the process chamber from a gas inlet element (8, 9) surrounding the processing roller (3) in the form of a ring.

A device which is characterized in that the processing roller (3) is heatable so that its surface temperature can be brought to a process temperature (T₂) that is higher than room temperature (T₁), wherein it is provided in particular that a heater arranged within the processing zone (3) generates an axial temperature profile with a maximum temperature at the center of the roller.

A device which is characterized in that the diameter of the processing roller (3) is greatest at its axial center, and the roller has in particular a lateral surface running along a rotational paraboloid.

A method which is characterized in that the coating is a graphene film or a film of nanotubes.

A method which is characterized in that the process gas is carbon-based and is in particular CH₄, C₂H₄, C₂H₂, C₆H₆.

A method, which is characterized in that the purifying gas is H₂, Ar, NH₃.

All the features disclosed here are essential (by themselves) for the invention. The disclosure content of the respective/ accompanying priority documents (photocopy of the previous patent application) is herewith fully incorporated into the disclosure of the present patent application, also for the purpose of including features of these documents in claims in the present application. The claims with their features characterized independent refinements of the prior art according to the invention, in particular for filing divisional applications on the basis of these claims.

### LIST OF REFERENCE NUMERALS

1 Substrate

1′ Substrate

2 Process chamber

3 Processing roller

4 Purification zone

5 Deposition zone

6 Coil

7 Coil

8 Gas inlet element, purging gas

9 Gas inlet element, process gas

10 Gas outlet element

11 Gas flow, purging gas

12 Gas flow, process gas

13 Opening

14 Loading chamber

15 Loading chamber

16 Inlet zone

17 Outlet zone

18 Axis

1. A device for processing a strip-type substrate (1), in particular by coating, in a processing chamber (2), using a processing roller (3) mounted to rotate about an axis of rotation (18) in the processing chamber (2), such that the substrate (1), which is unwound from a first coil (6) with which it is in contact in a helical pattern, is processed continuously, wherein the processed, in particular coated, substrate (1) is wound onto a second coil (7), wherein a gas inlet/outlet device (8, 9, 10) is provided for generating a gas stream (11, 12) directed essentially in parallel to the axis of rotation (18), forming a gas flow field extending around the entire circumference of the processing roller.

2. The device according to claim 1, characterized in that the gas inlet/outlet device (8, 9, 10) has a gas inlet element (8, 9).

3. The device according to claim 2, characterized in that the gas inlet/outlet device (8, 9, 10) has a gas inlet element (10).

4. The device according to claim 2, characterized in that the gas inlet element (8, 9) is designed in a ring shape.

5. The device according to claim 4, characterized in that the gas outlet element (10) is designed in a ring shape.

6. The device according to claim 5, characterized by a purification zone (4) and a deposition zone (5) arranged at an offset therefrom in the direction of the axis of rotation (18).

7. The device according to claim 4, characterized in that the ring-shaped gas inlet element (8, 9) has openings (13) opening in the direction of the axis of rotation (18).

8. The device according to claim 7, characterized in that the ring-shaped gas outlet element (10) has openings (13) opening in the direction of the axis of rotation (18).

9. The device according to claim 1, characterized by a gas outlet element (10) surrounding the processing roller (3) in a ring shape approximately at its axial center for accommodating a purifying gas and/or a process which is introduced in the process chamber from a gas inlet element (8, 9) surrounding the processing roller (3) in the form of a ring.

10. The device according to claim 1, characterized in that the processing roller (3) is heatable so that its surface temperature can be brought to a process temperature (T₂) which is above room temperature (T₁), wherein it is provided in particular that a heater arranged within the processing zone (3) generates an axial temperature profile with a maximum temperature at the center of the roller.

11. The device according to claim 1, characterized in that the diameter of the processing roller (3) is greatest at its axial center, and the roller has in particular a lateral surface running along a rotational paraboloid.

12. A method for coating a strip-type substrate (1) in a device according to one of the preceding claims, characterized in that the coating is a graphene film or a film of nanotubes.

13. The method according to claim 12, characterized in that the process gas is carbon-based and is in particular CH₄, C₂H₄, C₂H_{2,} C₆H₆.

14. The method according to claim 13, characterized in that the purifying gas is H₂, Ar, NH₃.

15. The device or method, characterized by the characterizing features of one of the preceding claims.
